(19) United States
(12) Patent Application Publication
(10) Pub. No.: US 2017/0279559 A1
(43) Pub. Date: Sep. 28, 2017

(54) TURBO EQUALIZATION DEVICE AND TURBO EQUALIZATION METHOD

(71) Applicant: Panasonic Corporation, Osaka (JP)

(72) Inventor: TAKENORI SAKAMOTO, Kanagawa (JP)

(21) Appl. No.: 15/453,481

(22) Filed: Mar. 8, 2017

(30) Foreign Application Priority Data
Mar. 23, 2016 (JP) 2016-058521

(51) Int. Cl. H04L 1/00; H03M 13/00; H03M 13/37; H04L 25/03; H03M 13/11

(52) U.S. Cl. CPC H04L 1/0051; H04L 25/03019; H04L 1/0058; H03M 13/1111; H03M 13/3753; H03M 13/6331; H04L 2025/03611

(57) ABSTRACT

A turbo equalization device includes equalization circuitry, which in operation, performs an equalization process M times on an input signal, M being an integer equal to or more than 1; counter circuitry, which in operation, counts an iteration number m that indicates a number of the performed equalization process, m being an integer equal to or more than 0 and equal to less than M; control circuitry, which in operation, determines an iteration number N of a decoding process for the m times equalization processed input signal according to the iteration number m of the equalization process, the decoding process using an error correcting code that uses a belief propagation algorithm, N being an integer equal to or more than 1; and decoding circuitry, which in operation, performs a decoding process N or less times on the m times equalization processed input signal.

### BACKGROUND

1. Technical Field

The present disclosure relates to a turbo equalization device and a turbo equalization method, and particularly to a turbo equalization device and a turbo equalization method using an error correcting code that uses a belief propagation algorithm.

2. Description of the Related Art

S. Oelcer and M. Keskinoz, “Performance of MMSE turbo equalization using outer LDPC coding for magnetic recording channels,” IEEE Int. Conf. on Commun. (ICC), vol. 2, pp. 645-650, June 2004 discloses a turbo equalization device, which uses a low-density parity check (LDPC) code as an error correcting code using a belief propagation algorithm. It is known that a turbo equalization device has a high equalizing capability.

A turbo equalization device attempts to remove and suppress inter-symbol interference by exchanging reliability information between an equalizer and an error correcting decoder to enhance reception performance. An LDPC code exerts a superior error correcting capability in combination with a sum-product decoding method, which is an iterative decoding algorithm.

### SUMMARY

A turbo equalization device can enhance reception performance by iteratively performing each of an equalization process and a decoding process. In other words, to obtain superior reception performance in a turbo equalization device, each of the equalization process and the decoding process needs a sufficient number of iterations. In a typical communication system, however, reception processing time of a reception device is restricted and accordingly, the numbers of iterations of the equalization process and the decoding process are restricted. Thus, it is difficult to obtain sufficient reception performance in a turbo equalization device.

One non-limiting and exemplary embodiment facilitates providing an equalization device and an equalization method, which can reduce the number of iterations of a decoding process while ensuring reception performance.

In one general aspect, the techniques disclosed here feature a turbo equalization device include: equalization circuitry, which in operation, performs an equalization process M times on an input signal, M being an integer equal to or more than 1; counter circuitry, which in operation, counts a iteration number m that indicates a number of the performed equalization process, m being an integer equal to or more than 0 and equal to less than M; control circuitry, which in operation, determines an iteration number N of a decoding process for the m times equalization processed input signal according to the iteration number m of the equalization process, the decoding process using an error correcting code that uses a belief propagation algorithm, N being an integer equal to or more than 1; and decoding circuitry, which in operation, performs a decoding process N or less times on the m times equalization processed input signal.

According to the present disclosure, the total number of times the decoding process is iterated can be reduced while reception performance is ensured.

It should be noted that general or specific embodiments may be implemented as a system, a device, a method, an integrated circuit, a computer program, a storage medium, or any selective combination thereof.

Additional benefits and advantages of the disclosed embodiments will become apparent from the specification and drawings. The benefits and/or advantages may be individually obtained by the various embodiments and features of the specification and drawings, which need not all be provided in order to obtain one or more of such benefits and/or advantages.

### BRIEF DESCRIPTION OF THE DRAWINGS

FIG. 1 illustrates an example of change in syndrome of each code word;

FIG. 2 illustrates an example of change in an average syndrome;

FIG. 3 illustrates an example of a configuration of a turbo equalization device according to an embodiment of the present disclosure;

FIG. 4 illustrates a first configuration example of a number-of-iterated-decodings controller according to an embodiment of the present disclosure;

FIG. 5 illustrates a second configuration example of the number-of-iterated-decodings controller according to an embodiment of the present disclosure;

FIG. 6 illustrates a third configuration example of the number-of-iterated-decodings controller according to an embodiment of the present disclosure;

FIG. 7 illustrates an example of a look-up table (LUT) according to an embodiment of the present disclosure; and

FIG. 8 illustrates a configuration example of a switch controller according to an embodiment of the present disclosure.

### DETAILED DESCRIPTION

### Circumstances Leading Up to an Aspect of the Present Disclosure

As a method for reducing the total number of times a decoding process is iterated when reception processing time is restricted, two methods described below are conceivable.

As the first method, the turbo equalization device disclosed in Japanese Patent No. 4838819 estimates the amount of increase in reliability of a result of a decoding process every time the decoding process is iterated and when the estimated amount of increase in reliability falls below a reference amount, the low-density parity check (LDPC) decoding process is suspended to transition to an equalization process, and when the estimated amount of increase in reliability exceeds the reference amount, the decoding process is continued. Accordingly, the turbo equalization device can reduce the total number of times the decoding process is iterated even under the conditions that make it difficult to expect increase in reliability.

Conceivable as the second method is a method where when it is difficult in a turbo equalization device to sufficiently remove and suppress the inter-symbol interference from the received signal due to the small number of iterations of the equalization process, the number of times the decoding process is iterated is set to be large, and when it is easy to sufficiently remove and suppress the inter-symbol interference from the received signal due to the large number of iterations of the equalization process. Accordingly, the total number of times the decoding process is iterated in the turbo equalization device can be reduced.

The present inventor, meanwhile, has noted the relation between the number of times an equalization process is iterated and the degree of improvement in reception performance through a iterative decoding process.

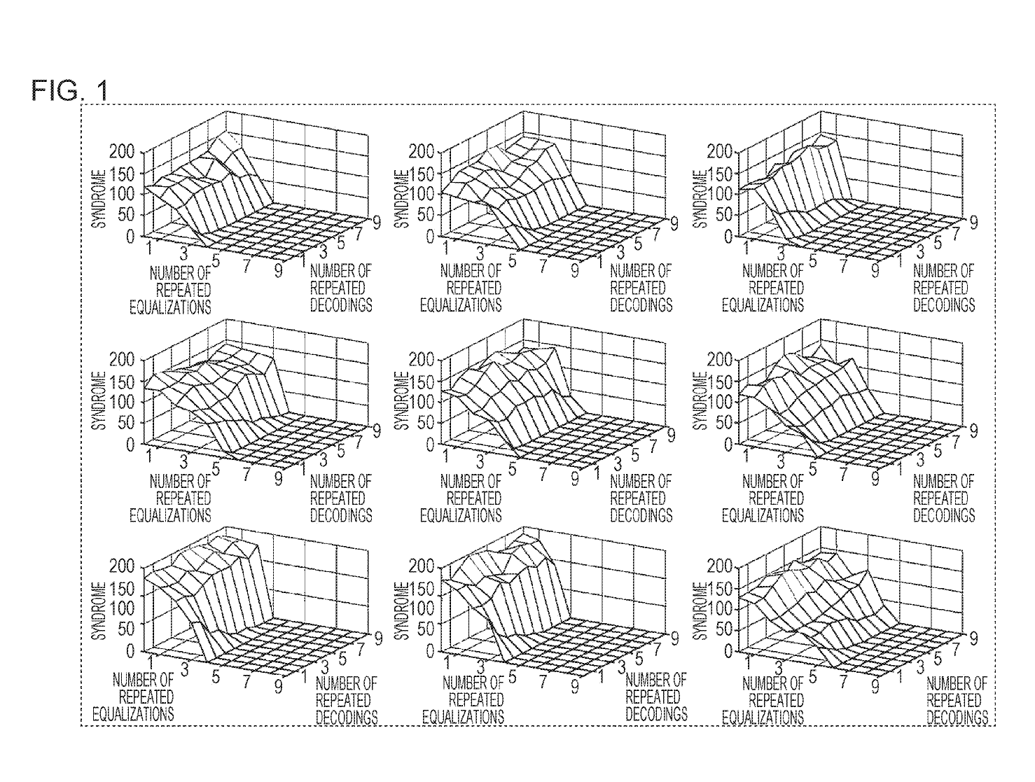

FIG. 1 illustrates an example of change in syndrome of each code word, that is, the syndromes of nine code words in a case where, on a certain channel, a turbo equalization device iterates nine decoding processes due to one equalization process. The turbo equalization device uses an LDPC code as an example of an error correcting code that uses a belief propagation algorithm.

The “syndrome” indicates the number of temporary estimation words where the parity check result in the decoding process indicates NG denoting that there is an error, and is one of pieces of information that expresses the reliability of the decoding process result. As the syndrome approaches zero, the reliability of the decoding process result becomes higher. When the syndrome reaches zero, it is implied that all bit errors are corrected.

The “number of iterated equalizations” indicates the number of times the equalization process is iterated. For example, when the equalization process is performed for the first time, the number of iterated equalizations is zero and when the equalization process is performed for the second time, that is, when the equalization process is iterated once, the number of repeated equalizations is one.

The “number of iterated decodings” indicates the number of times the decoding process is iterated. For example, when the decoding process is performed for the first time, the number of iterated decodings is zero and when the decoding process is performed for the second time, that is, when the decoding process is iterated once, the number of iterated decodings is one.

FIG. 1 demonstrates that when the number of iterated equalizations is small, the iteration of the decoding process causes neither monotone increase nor monotone decrease in the syndrome. That is, when the number of iterated equalizations is small, the syndrome (reliability) increases or decreases according to the conditions of the channel every time the decoding process is iterated.

In the above-described first method, therefore, the turbo equalization device disclosed in Japanese Patent No. 4838819 needs the number of iterated decodings that is not small so as to accurately estimate the amount of increase in reliability. Thus, in Japanese Patent No. 4838819, a phenomenon occurs, where it is difficult to ensure time for estimating the amount of increase in reliability in the reception processing time that is restricted, depending on the conditions of the channel.

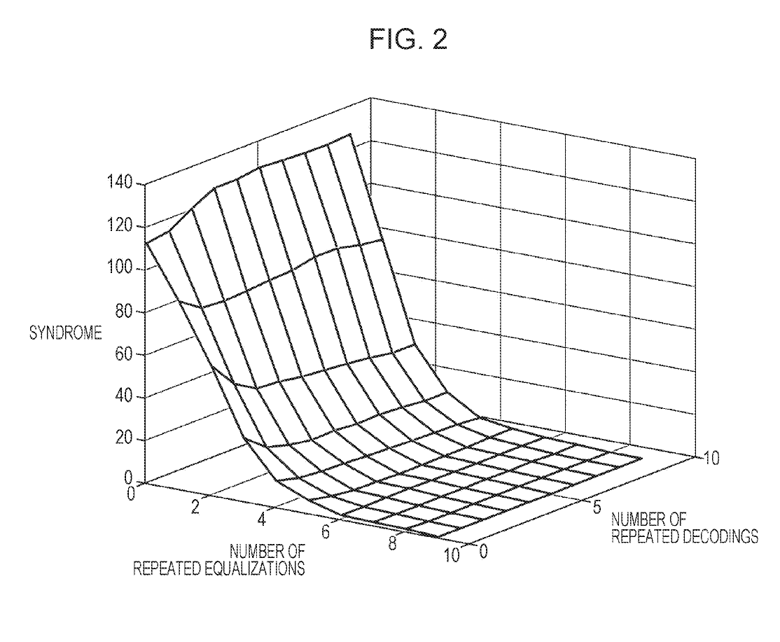

Similar to FIG. 1, FIG. 2 illustrates change in a syndrome, which is obtained by averaging the syndromes of 1000 code words in a case where the turbo equalization device iteratively performs equalization process and decoding process on a certain channel. The turbo equalization device uses an LDPC code as an example of an error correcting code that uses a belief propagation algorithm.

FIG. 2 demonstrates that when the number of iterated equalizations is small, which is zero or one for example, it is difficult to expect improvement in syndrome through the iteration of the decoding process. In contrast, it is demonstrated that when the number of iterated equalizations is small, the iteration of the equalization process improves the syndrome. That is, when the number of iterated equalizations is small, it is difficult to enhance the reception performance through the iteration of the decoding process.

FIG. 2 also demonstrates that when the number of iterated equalizations is large, which is two or more for example, the iteration of the decoding process improves the syndrome and the syndrome converges on zero. That is, in a state where inter-symbol interference is sufficiently removed from a received signal and suppressed through the iteration of the equalization process, the iteration of the decoding process can improve the syndrome and further enhance the reception performance. Examples of the received signal include video, voice, image, text data, and control data.

That is, when the number of iterated equalizations is small, the turbo equalization device can reduce needless iteration of the decoding process by repeating the equalization process by giving a higher priority to the equalization process than the decoding process and enhance the reception performance with efficiency. When the number of iterated equalizations is large, the turbo equalization device can enhance the reception performance by repeating the decoding process.

Accordingly, the method like the above-described second method, by which when the number of iterated equalizations is small, the number of times the decoding process is iterated is increased and when the number of iterated equalizations is large, the number of times the decoding process is iterated is decreased, can reduce the total number of times the decoding process is iterated but has difficulty in enhancing the reception performance through the decoding process.

Thus, in an aspect of the present disclosure, to ensure the reception performance even in a communication system where reception processing time is restricted, the turbo equalization device determines the maximum number of times the decoding process is iterated, depending on the number of times the equalization process is iterated. Specifically, the turbo equalization device performs the determination so that, at least, the maximum number of times the decoding process is iterated in a case where the number of times the equalization process is iterated is the largest is larger than the maximum number of times the decoding process is iterated in a case where the number of times the equalization process is iterated is the smallest.

An embodiment of the present disclosure is described in detail below by referring to the drawings as appropriate.

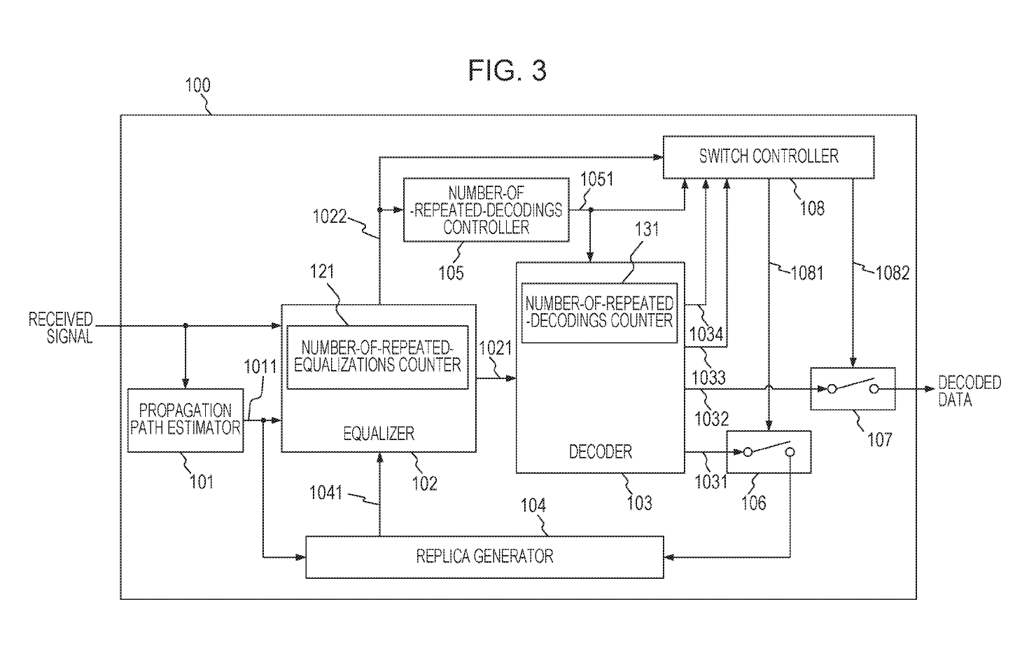

FIG. 3 is a block diagram that illustrates a configuration of a turbo equalization device 100 according to the present embodiment. The turbo equalization device 100 illustrated in FIG. 3 uses an LDPC code as an example of an error correcting code that uses a belief propagation algorithm.

The turbo equalization device 100 includes a channel estimator 101, an equalizer 102, a decoder 103, a replica generator 104, a number-of-iterated-decodings controller 105, switches 106 and 107, and a switch controller 108.

The channel estimator 101 estimates characteristics of a channel between a transmitter, which is not illustrated, and a receiver including the turbo equalization device 100, which is not illustrated, using a received signal that is input and outputs a channel estimation result 1011 to each of the equalizer 102 and the replica generator 104.

The equalizer 102 iteratively performs an equalization process on the input, received signal using the channel estimation result 1011 and a replica signal 1041 input from the replica generator 104. That is, the equalizer 102 removes an inter-symbol interference component included in the received signal and suppresses an inter-symbol interference component on the basis of the channel estimation result 1011. The equalizer 102 outputs the equalization signal 1021, which is a resultant signal after the equalization process, to the decoder 103. The maximum number of times the equalization process is iterated may be set in advance.

The equalizer 102 includes a number-of-iterated-equalizations counter 121 inside. The number-of-iterated-equalizations counter 121 counts the number of times the equalization process is iterated. The number-of-iterated-equalizations counter 121 outputs the number of iterated equalizations, 1022, which is the counted number of times of the iteration, to each of the number-of-iterated-decodings controller 105 and the switch controller 108. By the way, The number-of-iterated-equalizations counter 121 resets the number of iterated equalizations, 1022 to zero for each LDPC codeword.

The decoder 103 uses an LDPC code as an example of an error correcting code that uses a belief propagation algorithm. The decoder 103 performs an error correcting process (a decoding process) on the equalization signal 1021, outputs a soft decision result 1031 to the switch 106, outputs a hard decision result 1032 to the switch 107, and outputs a parity check result 1033 to the switch controller 108. The parity check result 1033 is a signal that is “true” when the parity check result indicates OK denoting that there is no error.

The decoder 103 iteratively performs the decoding process while a maximum number of iterated decodings 1051, which is input from the number-of-iterated-decodings controller 105 and indicates the maximum number of times the LDPC decoding process is iterated, serves as an upper limit.

The decoder 103 includes a number-of-iterated-decodings counter 131 inside. The number-of-iterated-decodings counter 131 counts the number of iterated decodings, 1034, which indicates the number of times the decoding process is iterated. The number-of-iterated-decodings counter 131 outputs the counted number of iterated decodings 1034 to the switch controller 108.

The replica generator 104 generates the replica signal 1041 of the received signal on the basis of the channel estimation result 1011 and the soft decision result 1031 input via the switch 106. The replica generator 104 outputs the generated replica signal 1041 to the equalizer 102.

The number-of-iterated-decodings controller 105 determines the maximum number of iterated decodings 1051 that indicates the maximum number of times the decoding process is iterated on the basis of the number of iterated equalizations 1022 input from the equalizer 102. The number-of-iterated-decodings controller 105 determines the maximum number of iterated decodings 1051 for each number of times the equalization process is iterated.

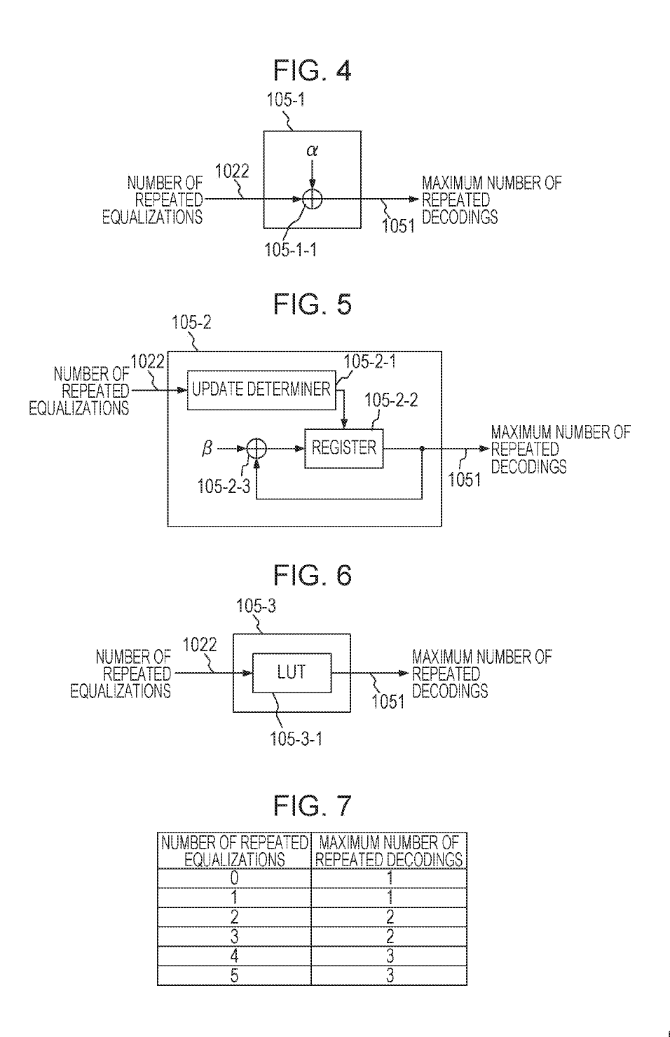

FIGS. 4 to 6 illustrate first to third configuration examples of the number-of-iterated-decodings controller 105, respectively.

In the first configuration example illustrated in FIG. 4, the number-of-iterated-decodings controller 105-1 determines the maximum number of iterated decodings 1051 by adding a predetermined number α, which represents a positive integer, with an adder 105-1-1 to the number of iterated equalizations 1022 that is input. That is, the number-of-iterated-decodings controller 105-1 determines the maximum number of iterated decodings 1051 so that the maximum number of iterated decodings 1051 relative to the number of iterated equalizations 1022 becomes larger with increase in the number of iterated equalizations 1022. In other words, the number-of-repeated-decodings controller 105-1 performs the determination so that as the number of repeated equalizations 1022 becomes larger, the maximum number of repeated decodings 1051 relative to the equalization signal 1021 (an output signal) at the number of repeated equalizations 1022 becomes larger.

In the second configuration example illustrated in FIG. 5, the number-of-iterated-decodings controller 105-2 stores the maximum number of iterated decodings 1051 in a case where the number of times the equalization process is iterated is the smallest, that is, the number of iterated equalizations 1022 is zero, as an initial value of a register 105-2-2 in advance. After that, when an update determiner 105-2-1 determines that the number of iterated equalizations 1022 is updated, that is, when the equalization process is iterated, the number-of-iterated-decodings controller 105-2 determines the value of the maximum number of iterated decodings 1051 of the decoding process by adding a predetermined number β, which is a positive integer, with an adder 105-2-3 to the value stored in the register 105-2-2.

Accordingly, compared to the number-of-iterated-decodings controller 105-1 of the first configuration example, the number-of-iterated-decodings controller 105-2 of the second configuration example can set the initial value of the maximum number of iterated decodings 1051 as desired. Similar to the number-of-iterated-decodings controller 105-1 of the first configuration example, the number-of-iterated-decodings controller 105-2 of the second configuration example determines the maximum number of iterated decodings 1051 so that with increase in the number of iterated equalizations 1022, the maximum number of iterated decodings 1051 relative to the number of iterated equalizations 1022 becomes larger. That is, the number-of-repeated-decodings controller 105-2 performs the determination so that as the number of repeated equalizations 1022 becomes larger, the maximum number of repeated decodings 1051 for the equalization signal 1021 at the number of repeated equalizations 1022 becomes larger.

In the third configuration example illustrated in FIG. 6, the number-of-iterated-decodings controller 105-3 includes a look-up table (LUT) 105-3-1 and determines the maximum number of iterated decodings 1051 according to the LUT 105-3-1. In the LUT 105-3-1, the number of iterated equalizations 1022 and the maximum number of iterated decodings 1051 are related to each other. The number-of-iterated-decodings controller 105-3 reads the value of the maximum number of iterated decodings 1051, which is related to the value of the input number of iterated equalizations 1022, from the LUT 105-3-1.

FIG. 7 illustrates an example of the LUT 105-3-1. In FIG. 7, the upper limit to the number of iterated equalizations 1022 is five, that is, the number of iterated equalizations 1022 ranges from 0 to 5 and the values of the maximum numbers of iterated decodings are respectively related to the values of the numbers of iterated equalizations.

For instance, in an example of the LUT 105-3-1 in FIG. 7, when the number of iterated equalizations 1022 is zero, the maximum number of iterated decodings 1051 is one and when the number of iterated equalizations 1022 is five, the maximum number of iterated decodings 1051 is three. That is, in the first configuration example or the second configuration example, the maximum number of iterated decodings increases monotonously together with increase in the number of iterated equalizations 1022 while in the third configuration example, the degree of increase in the maximum number of iterated decodings 1051 relative to the increase in the number of iterated equalizations 1022 may be set as desired. Accordingly, the number-of-iterated-decodings controller 105-3 of the third configuration example can set the value of the maximum number of iterated decodings 1051 for the value of each number of iterated equalizations more suitably than the number-of-iterated-decodings controller 105-1 of the first configuration example and the number-of-iterated-decodings controller 105-2 of the second configuration example.

The first to third configuration examples of the number-of-iterated-decodings controller 105 are described above.

Thus, in the first to third configuration examples, the number-of-iterated-decodings controller 105 determines the maximum number of iterated decodings 1051 for each number of iterated equalizations 1022 so that the maximum number of iterated decodings 1051 in a case where the number of iterated equalizations 1022 of the equalization process is the largest is larger than the maximum number of iterated decodings 1051 in a case where the number of iterated equalizations 1022 of the equalization process is the smallest.

The switch 106 outputs the soft decision result 1031 to the replica generator 104 in accordance with a switch control signal 1081 input from the switch controller 108.

The switch 107 outputs the hard decision result 1032 as the decoded data in accordance with a switch control signal 1082 input from the switch controller 108.

The switch controller 108 controls the open and closed (ON and OFF) states of the switch 106 and the switch 107 on the basis of the number of iterated equalizations 1022, the number of iterated decodings 1034, the parity check result 1033, and the maximum number of iterated decodings 1051.

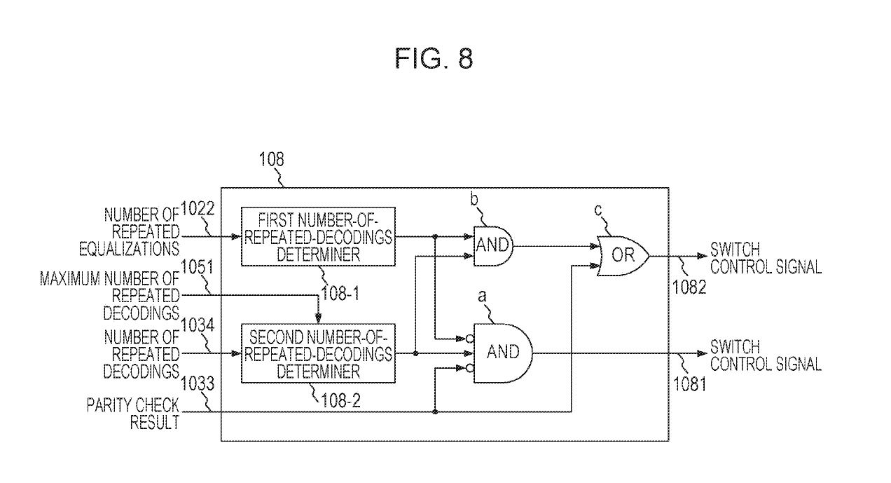

FIG. 8 is a block diagram that illustrates a configuration example of the switch controller 108.

The switch controller 108 turns on the switch 106 using the switch control signal 1081 when a second number-of-iterated-decodings determiner 108-2 determines that the number of iterated decodings 1034 has reached the maximum number of iterated decodings 1051, when the parity check result 1033 indicates NG denoting that there is an error, and when the number of iterated equalizations 1022 has not reached the maximum number of times the equalization process is iterated, which is predetermined, that is, when an AND operation a illustrated in FIG. 8 is “true”. Accordingly, the turbo equalization device 100 iterates equalization process.

Further, the switch controller 108 turns on the switch 107 using the switch control signal 1082 when the second number-of-iterated-decodings determiner 108-2 determines that the number of iterated decodings 1034 has reached the set maximum number of times of the iteration and when the first number-of-iterated-decodings determiner 108-1 determines that the number of iterated equalizations 1022 has reached the set maximum number of times of the iteration, that is, when an AND operation b is “true” or when the parity check result 1033 indicates OK denoting that there is no error, that is, when an OR operation c is “true”. Accordingly, the turbo equalization device 100 outputs the hard decision result 1032 generated in the decoder 103 as the decoded data.

As described above, according to the present embodiment, the turbo equalization device 100 determines the maximum number of times the decoding process is iterated in the decoder 103 on the basis of the number of iterated equalizations in the equalizer 102.

Specifically, the maximum number of times the decoding process is iterated in a case where the number of times the equalization process is iterated in the equalizer 102 is small is set by the turbo equalization device 100 so as to be smaller than the maximum number of times the decoding process is iterated in a case where the number of times the equalization process is iterated is large, that is, in a case with the number of iterated equalizations that enables improvement in syndrome through the iteration of the decoding process to be expected.

This is because in the turbo equalization device 100, when the number of times the equalization process is iterated is small, it is difficult to expect improvement in syndrome through the iteration of the decoding process (see FIG. 2 for example).

When the number of times the equalization process is iterated is small, the turbo equalization device 100 can reduce needless iteration of the decoding process by repeating the equalization process in the equalizer 102 by giving a higher priority to the equalization process than the decoding process and enhance the reception performance with efficiency.

In contrast, when the number of times the equalization process is iterated is large, that is, when inter-symbol interference is sufficiently removed from a received signal and suppressed through the iteration of the equalization process, improvement in syndrome can be expected through the iteration of the decoding process in the turbo equalization device 100 (see FIG. 2 for example). Thus, the turbo equalization device 100 can enhance the reception performance by repeating the LDPC decoding process in the decoder 103.

Since the turbo equalization device 100 determines the maximum number of times the decoding process is iterated according to the number of times the equalization process is iterated, favorable reception performance can be obtained without depending on the channel conditions, that is, the amount of improvement in syndrome.

As described above, according to the present embodiment, the turbo equalization device 100 can reduce the number of times the decoding process is iterated. As a result, the turbo equalization device 100 can ensure reception performance even in a communication system where reception processing time is restricted.

Although various embodiment examples are described above with reference to the drawings, it is needless to mention that the present disclosure is not limited to such examples. A person skilled in the art may arrive at variations or modifications within the scope recited in the claims, and the variations or modifications should be understood as belonging in the technical scope of the present disclosure as a matter of course.

Although the above-described embodiment is described by taking a case where an aspect of the present disclosure is configured with hardware as an example, the present disclosure can be implemented with software in conjunction with hardware.

Each of the functional blocks used in describing the embodiments above is typically implemented as large-scale integration (LSI), which is an integrated circuit (IC). The IC may control each functional block used in describing the embodiments above and may be provided with an input terminal and an output terminal. These may be made individually as single chips or may be made as a single chip so as to include part or all. Depending on the degree of the integration, the LSI, which is mentioned herein, may also be referred to as an IC, system LSI, super LSI, or ultra LSI.

In addition, techniques of the circuit integration are not limited to the LSI, a dedicated circuit or a general-purpose processor may be used for the implementation. A field-programmable gate array (FPGA), which is programmable after manufacturing the LSI, or a reconfigurable processor, which allows reconfiguring the connection and setting of circuit cells inside the LSI after manufacturing the LSI, may be utilized.

Moreover, when other techniques of the circuit integration that replace the LSI are brought by advance of semiconductor techniques or other derivative techniques, the functional blocks may be integrated by such techniques of course. Application of biotechnology is possible, for example.

Various aspects of embodiments according to the present disclosure include what is described below.

A turbo equalization device according to the present disclosure includes: equalization circuitry, which in operation, performs an equalization process M times on an input signal, M being an integer equal to or more than 1; counter circuitry, which in operation, counts a iteration number m that indicates a number of the performed equalization process, m being an integer equal to or more than 0 and equal to less than M; control circuitry, which in operation, determines a iteration number N of a decoding process for the m times equalization processed input signal according to the iteration number m of the equalization process, the decoding process using an error correcting code that uses a belief propagation algorithm, N being an integer equal to or more than 1; and decoding circuitry, which in operation, performs a decoding process N or less times on the m times equalization processed input signal.

In the turbo equalization device according to the present disclosure, the control circuitry may determines the iteration number N of the decoding process for the M times equalization processed input signal to be a value larger than the iteration number N of the decoding process for one times equalization processed input signal.

In the turbo equalization device according to the present disclosure, the control circuitry may determines the iteration number N of the decoding process for the m times equalization processed input signal to be a value that increases as the iteration number m of the equalization process increases.

In the turbo equalization device according to the present disclosure, the control circuitry may include a look-up table (LUT) where the iteration number m of the equalization process and the iteration number N of the decoding process are related to each other, and determine the iteration number N of the decoding process is repeated according to the LUT.

In the turbo equalization device according to the present disclosure the error correcting code may be a low-density parity check (LDPC) code.

A turbo equalization method according to the present disclosure includes: performing an equalization process M times on an input signal, M being an integer equal to or more than 1; counting a iteration number m that indicates a number of the performed equalization process, m being an integer equal to or more than 0 and equal to less than M; determining a iteration number N of a decoding process for the m times equalization processed input signal according to the iteration number m of the equalization process, the decoding process using an error correcting code that uses a belief propagation algorithm, N being an integer equal to or more than 1; and performing a decoding process N or less times on the m times equalization processed input signal.

The present disclosure is suitable for a turbo equalization device using an error correcting code that uses a belief propagation algorithm.

What is claimed is:

1. A turbo equalization device comprising:
equalization circuitry, which in operation, performs an equalization process M times on an input signal, M being an integer equal to or more than 1;
counter circuitry, which in operation, counts an iteration number m that indicates a number of the performed equalization process, m being an integer equal to or more than 0 and equal to less than M;
control circuitry, which in operation, determines an iteration number N of a decoding process for the m times equalization processed input signal according to the iteration number m of the equalization process, the decoding process using an error correcting code that uses a belief propagation algorithm, N is an integer equal to or more than 1; and
decoding circuitry, which in operation, performs a decoding process N or less times on the m times equalization processed input signal.

2. The turbo equalization device according to claim 1, wherein
the control circuitry determines the iteration number N of the decoding process for the M times equalization processed input signal to be a value larger than the iteration number N of the decoding process for one times equalization processed input signal.

3. The turbo equalization device according to claim 2, wherein
the control circuitry determines the iteration number N of the decoding process for the m times equalization processed input signal to be a value that increases as the iteration number m of the equalization process increases.

4. The turbo equalization device according to claim 2, wherein
the control circuitry
includes a look-up table (LUT) where the iteration number m of the equalization process and the iteration number N of the decoding process are related to each other, and
determines the iteration number N of the decoding process is iterated according to the LUT.

5. The turbo equalization device according to claim 1, wherein
the error correcting code is a low-density parity check (LDPC) code.

6. A turbo equalization method comprising:
performing an equalization process M times on an input signal, M being an integer equal to or more than 1;
counting an iteration number m that indicates a number of the performed equalization process, m being an integer equal to or more than 0 and equal to less than M;
determining an iteration number N of a decoding process for the m times equalization processed input signal according to the iteration number m of the equalization process, the decoding process using an error correcting code that uses a belief propagation algorithm, N being an integer equal to or more than 1; and
performing a decoding process N or less times on the m times equalization processed input signal.
